(19) United States
(12) Patent Application Publication
(10) Pub. No.: US 2016/0079255 A1
(43) Pub. Date: Mar. 17, 2016

(54) NON-VOLATILE SEMICONDUCTOR MEMORY DEVICE AND METHOD FOR MANUFACTURING SAME

(71) Applicant: Kabushiki Kaisha Toshiba, Minato-ku (JP)

(72) Inventors: Takeshi SONEHARA, Yokkaichi (JP); Masaru KITO, Kuwana (JP); Takashi SHIMIZU, Kashiwa (JP); Yoshihiro AKUTSU, Yokkaichi (JP)

(73) Assignee: Kabushiki Kaisha Toshiba, Minato-ku (JP)

(21) Appl. No.: 14/818,584

(22) Filed: Aug. 5, 2015

(30) Foreign Application Priority Data
Sep. 12, 2014 (JP) 2014-186924

(51) Int. Cl. H01L 27/115; H01L 29/423; H01L 29/06

(52) U.S. Cl. CPC H01L 27/11568; H01L 27/11582; H01L 29/0619; H01L 29/0642; H01L 29/42344

(57) ABSTRACT

According to one embodiment, a stacked body includes electrode layers and first insulating layers alternately stacked. An isolation region extends in the stacked body, the isolation region dividing the stacked body into first regions. First semiconductor members extend in one of the first regions in a stacked direction of the stacked body. A memory film is provided between one of the first semiconductor members and one of the electrode layers. A insulating region extends in the one of the first regions in the stacked direction. A composition of a second region of the one of the electrode layers is different from a composition of a third region of the one of the electrode layers. The second region is in contact with the insulating region, the third region being in contact with the isolation region.

### CROSS-REFERENCE TO RELATED APPLICATIONS

This application is based upon and claims the benefit of priority from Japanese Patent Application No. 2014-186924, filed on Sep. 12, 2014; the entire contents of which are incorporated herein by reference.

### FIELD

Embodiments described herein relate generally to a non-volatile semiconductor memory device and a method for manufacturing the same.

### BACKGROUND

As a non-volatile semiconductor memory device having a large memory capacity, an electrically rewritable three-dimensional flash memory has been attracting attention. In such a memory, a voltage required for writing and erasing is appropriately set by a material forming the memory.

However, a plurality of memory cells included in the memory are connected to each of the respective bit lines, word lines, and source lines. Due to this, a voltage is sometimes applied also to a memory cell other than a memory cell of an operation target. In other words, an unnecessary voltage is applied to a cell of a non-operation target. It is necessary to suppress the unnecessary voltage to the cell of the non-operation target and apply an intended voltage to the memory cell of the operation target. Therefore, it is necessary to reliably suppress a current leak between memory cells.

### BRIEF DESCRIPTION OF THE DRAWINGS

FIG. 1 is a schematic perspective view showing a part of a memory cell array of a non-volatile semiconductor memory device according to a first embodiment;

FIG. 2A is a schematic plan view showing the memory cell array of the non-volatile semiconductor memory device according to the first embodiment, and FIG. 2B is a schematic cross-sectional view taken along the line A-B of FIG. 2A;

FIG. 3A is a schematic cross-sectional view showing the silicidation process according to the first embodiment, and FIGS. 3B and 3C are schematic perspective views showing the silicidation process according to the first embodiment;

FIG. 4A is a schematic cross-sectional view showing the silicidation process according to the first embodiment, and FIGS. 4B and 4C are schematic perspective views showing the silicidation process according to the first embodiment;

FIG. 5A is a schematic cross-sectional view showing the silicidation process according to the first embodiment, and FIGS. 5B and 5C are schematic perspective views showing the silicidation process according to the first embodiment;

FIG. 6A is a schematic cross-sectional view showing the silicidation process according to the first embodiment, and FIGS. 6B and 6C are schematic perspective views showing the silicidation process according to the first embodiment;

FIG. 7A is a schematic cross-sectional view showing the silicidation process according to the first embodiment, and FIGS. 7B and 7C are schematic perspective views showing the silicidation process according to the first embodiment;

FIG. 8A to FIG. 8D are schematic perspective views showing a silicidation process according to a reference example;

FIG. 9A to FIG. 9B are schematic perspective views showing a silicidation process according to a variation 1 of the first embodiment;

FIG. 10A to FIG. 10B are schematic perspective views showing the silicidation process according to the variation 1 of the first embodiment;

FIG. 11A to FIG. 11B are schematic perspective views showing the silicidation process according to the variation 1 of the first embodiment;

FIG. 12A to FIG. 12C are schematic perspective views showing a silicidation process according to a variation 2 of the first embodiment;

FIG. 13A to FIG. 13B are schematic perspective views showing a silicidation process according to a variation 3 of the first embodiment;

FIG. 14A is a schematic cross-sectional view showing a production process according to a second embodiment, and FIG. 14B is a schematic plan view showing the production process according to the second embodiment; and

FIG. 15A is a schematic cross-sectional view showing a production process according to a variation 1 of the second embodiment, and FIG. 15B is a schematic plan view showing the production process according to the variation 1 of the second embodiment.

### DETAILED DESCRIPTION

According to one embodiment, a non-volatile semiconductor memory device includes a stacked body; an isolation region; a plurality of first semiconductor members; a memory film; and an insulating region. The stacked body includes a plurality of electrode layers and a plurality of first insulating layers alternately stacked. The isolation region extends in the stacked body, the isolation region dividing the stacked body into a plurality of first regions. The plurality of first semiconductor members extend in one of the first regions in a stacked direction of the stacked body. The memory film is provided between one of the first semiconductor members and one of the electrode layers. The insulating region extends in the one of the first regions in the stacked direction, the insulating region extends from an upper end of the one of the first regions to a lowest first insulating layer of the first insulating layers. A composition of a second region of the one of the electrode layers is different from a composition of a third region of the one of the electrode layers. The second region is in contact with the insulating region, the third region being in contact with the isolation region.

Various embodiments will be described hereinafter with reference to the accompanying drawings. In the following description, identical members are marked with identical reference numerals, and a description of a member once described will be omitted as appropriate.

### First Embodiment

First, an outline of a configuration of a non-volatile semiconductor memory device 1 according to a first embodiment will be described.

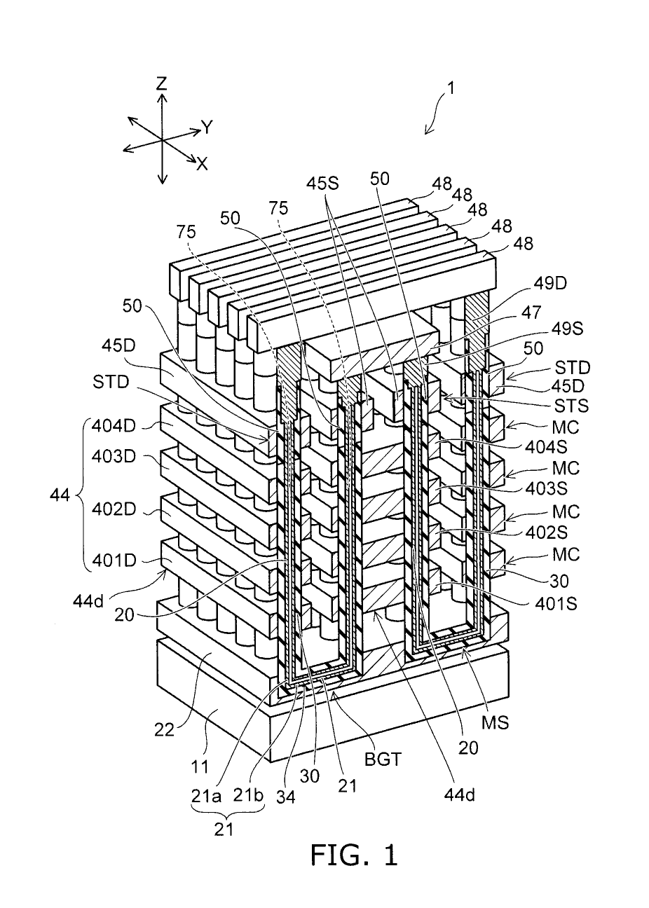

FIG. 1 is a schematic perspective view showing a part of a memory cell array of the non-volatile semiconductor memory device according to the first embodiment.

In FIG. 1, an illustration of an insulating portion other than an insulating film formed on an inner wall of a memory hole 75 is omitted. The non-volatile semiconductor memory device 1 is a three-dimensional stacked non-volatile semiconductor memory device.

In FIG. 1, an XYZ orthogonal coordinate system is introduced for the sake of convenience of explanation. In this coordinate system, two directions parallel to the major surface of a foundation layer 11 and orthogonal to each other are defined as an X-direction and a Y-direction, and a direction orthogonal to both of these X-direction and Y-direction is defined as a Z-direction.

The non-volatile semiconductor memory device 1 according to the first embodiment is a non-volatile semiconductor memory device capable of electrically erasing and writing data freely, and retaining storage contents even after the power is turned off.

In the non-volatile semiconductor memory device 1, on the foundation layer 11, a semiconductor layer 22 (back gate layer) is provided through an insulating layer (not shown). The foundation layer 11 includes a semiconductor substrate (for example, a silicon substrate), an insulating layer (for example, an SiO₂ layer), a circuit, and the like. For example, in the foundation layer 11, an active element such as a transistor and a passive element such as a resistor or a capacitor are provided. The semiconductor layer 22 is, for example, a silicon (Si) layer doped with an impurity element such as boron (B).

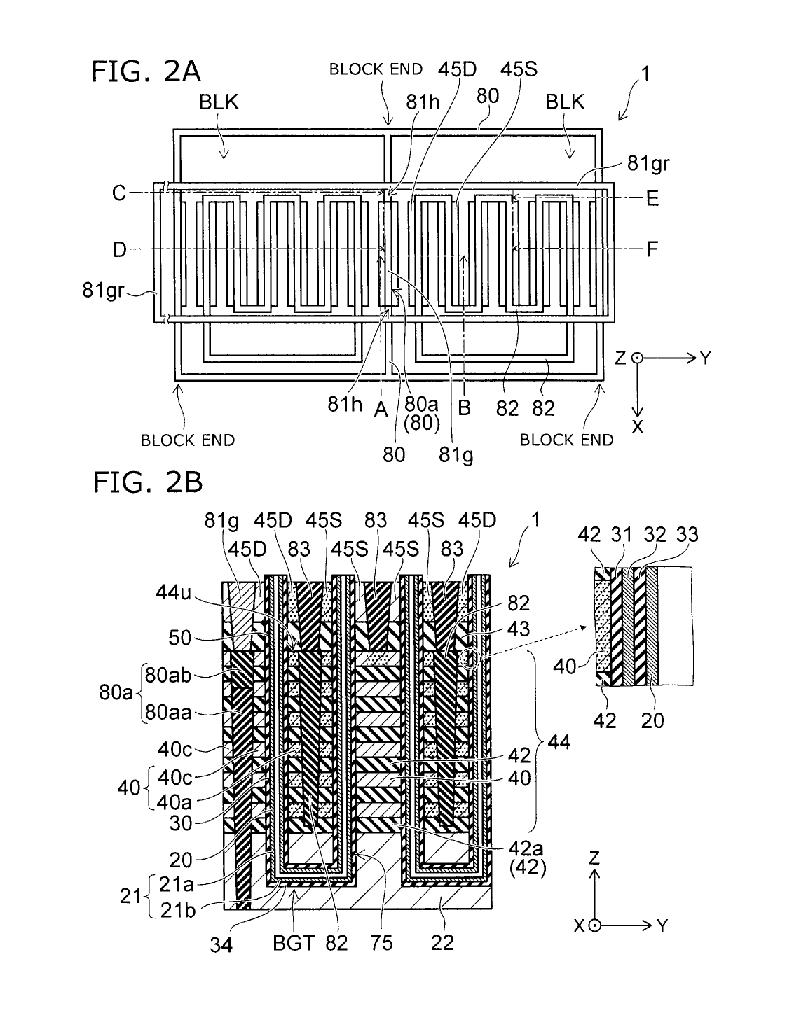

On the semiconductor layer 22, electrode layers 401D, 402D, 403D, and 404D on a drain side, and electrode layers 401S, 402S, 403S, and 404S on a source side are stacked. In the Z-direction, an insulating layer 42 (not shown in FIG. 1, see FIG. 2B) is provided between these electrode layers. A material of the insulating layer 42 includes, for example, a silicon oxide (SiO₂).

The electrode layer 401D and the electrode layer 401S are provided on the same level and each represent an electrode layer of the first layer from the bottom. The electrode layer 402D and the electrode layer 402S are provided on the same level and each represent an electrode layer of the second layer from the bottom. The electrode layer 403D and the electrode layer 403S are provided on the same level and each represent an electrode layer of the third layer from the bottom. The electrode layer 404D and the electrode layer 404S are provided on the same level and each represent an electrode layer of the fourth layer from the bottom.

The electrode layer 401D and the electrode layer 401S are divided in the Y-direction. The electrode layer 402D and the electrode layer 402S are divided in the Y-direction. The electrode layer 403D and the electrode layer 403S are divided in the Y-direction. The electrode layer 404D and the electrode layer 404S are divided in the Y-direction.

An insulating layer (not shown) is provided between the electrode layer 401D and the electrode layer 401S, between the electrode layer 402D and the electrode layer 402S, between the electrode layer 403D and the electrode layer 403S, and between the electrode layer 404D and the electrode layer 404S.

The electrode layers 401D, 402D, 403D, and 404D are provided between the semiconductor layer 22 and a drain-side selection gate electrode 45D. The electrode layers 401S, 402S, 403S, and 404S are provided between the semiconductor layer 22 and a source-side selection gate electrode 45S.

Further, in the following description, the electrode layers 401D, 402D, 403D, 404D, 401S, 402S, 403S, and 404S are sometimes referred to as simply “electrode layer 40”. The electrode layer 40 is a word line of an NAND string. Further, the number of the electrode layers 40 is arbitrary, and may be 4 or more as shown in the drawing to be described below. Further, the electrode layers 40 and the insulating layers 42 are collectively called a stacked body 44. The stacked direction of the stacked body 44 is set to the Z-direction. The lower surface of the electrode layer 401D (or the electrode layer 401S) of the first layer is a lower end 44d of the stacked body 44. The electrode layer 40 is, for example, a silicon layer which is doped with an impurity element such as boron (B) and has conductivity.

On the electrode layer 404D, the drain-side selection gate electrode 45D is provided through an insulating layer (not shown). The drain-side selection gate electrode 45D is, for example, a silicon layer which is doped with an impurity such as boron (B) and has conductivity.

On the electrode layer 404S, the source-side selection gate electrode 45S is provided through an insulating layer (not shown). The source-side selection gate electrode 45S is, for example, a silicon layer which is doped with an impurity such as boron (B) and has conductivity.

The drain-side selection gate electrode 45D and the source-side selection gate electrode 45S are divided in the Y-direction. Incidentally, the drain-side selection gate electrode 45D and the source-side selection gate electrode 45S are sometimes referred to as simply “selection gate electrode 45” without distinction.

On the source-side selection gate electrode 45S, a source line 47 is provided through an insulating layer (not shown). The source line 47 is connected to one end of a pair of channel body layers (first semiconductor members) 20 through a via 49S. The source line 47 is a metal wire or a conductive silicon layer doped with an impurity.

On the drain-side selection gate electrode 45D and the source line 47, a plurality of bit lines 48 are provided through an insulating layer (not shown). The bit line 48 is a metal wire or a conductive silicon layer doped with an impurity. The bit lines 48 are connected to the other end of the pair of channel body layers 20 through a via 49D. The bit lines 48 extend in the Y-direction. The via 49S and the via 49D are sometimes referred to as simply “via 49” without distinction. A material of the via 49 is, for example, tungsten (W).

The semiconductor layer 22 below the stacked body 44 and the stacked body 44 are provided with a plurality of U-shaped memory holes 75. For example, in the electrode layers 401D to 404D and the drain-side selection gate electrode 45D, a hole penetrating therethrough and extending in the Z-direction is formed. In the electrode layers 401S to 404S and the source-side selection gate electrode 45S, a hole penetrating therethrough and extending in the Z-direction is formed. Such a pair of holes extending in the Z-direction are connected to each other through the semiconductor layer 22 to form the U-shaped memory hole 75. Incidentally, in the first embodiment, other than the U-shaped memory holes 75, straight memory holes are also included.

In the inside of the memory hole 75, a U-shaped channel body layer 20 is provided. The channel body layer 20 is, for example, a silicon-containing layer. This silicon is, for example, polysilicon. Between the channel body layer 20 and the inner wall of the memory hole 75, a memory film 30 is provided (described below).

Between the channel body layer 20 and the drain-side selection gate electrode 45D, a gate insulating film 50 is provided. Between the channel body layer 20 and the source-side selection gate electrode 45S, a gate insulating film 50 is provided.

The configuration is not limited to the configuration in which the memory hole 75 is entirely filled with the channel body layer 20, and a configuration in which the channel body layer 20 is formed therein such that a hollow portion is left on the side of the central axis of the memory hole 75, and the hollow portion therein is filled with an insulating material may be adopted.

The drain-side selection gate electrode 45D, the channel body layer 20, and the gate insulating film 50 provided therebetween form a drain-side selection gate transistor STD. The channel body layer 20 in the upper part of the drain-side selection gate transistor STD is electrically connected to the bit line 48.

The source-side selection gate electrode 45S, the channel body layer 20, and the gate insulating film 50 provided therebetween form a source-side selection gate transistor STS. The channel body layer 20 in the upper part of the source-side selection gate transistor STS is electrically connected to the source line 47.

The drain-side selection gate transistor STD and the source-side selection gate transistor STS are each a cylindrical transistor.

The semiconductor layer 22, and the channel body layer 20 and the memory film 30, each provided in the semiconductor layer 22, form a back gate layer transistor BGT.

Between the drain-side selection gate transistor STD and the back gate layer transistor BGT, a plurality of memory cells MC having the electrode layers 404D to 401D as a control gate are provided. Similarly, also between the back gate layer transistor BGT and the source-side selection gate transistor STS, a plurality of memory cells MC having the electrode layers 401S to 404S as a control gate are provided.

These memory cells MC, the drain-side selection gate transistor STD, the back gate layer transistor BGT, and the source-side selection gate transistor STS are connected in series through the channel body layer to form one U-shaped memory string (NAND string) MS.

One memory string MS has the pair of the channel body layers 20 extending in the stacked direction (Z-direction) of the stacked body 44 including the plurality of electrode layers 40 and a channel body layer (second semiconductor member) 21 connected to the pair of the channel body layers 20. The channel body layer 21 is buried in the semiconductor layer 22 via an insulating film 34. The channel body layer 21 has a pair of first portions 21a extending in the Z-direction and a second portion 21b extending in the Y-direction connected to the first portions 21a in the semiconductor layer 22. Each of the pair of the channel body layers 20 is connected to each of the pair of first portions 21a. By arranging the plurality of memory strings MS in the X-direction and the Y-direction, the plurality of memory cells are three-dimensionally provided in the X-direction, the Y-direction, and the Z-direction.

The plurality of memory strings MS are provided in a memory cell array region in the foundation layer 11. For example, on the periphery of the memory cell array region in the foundation layer 11, a peripheral circuit which controls the memory cell array is provided.

FIG. 2A is a schematic plan view showing a memory cell array of the non-volatile semiconductor memory device according to the first embodiment, and FIG. 2B is a schematic cross-sectional view taken along the line A-B of FIG. 2A.

Here, in FIG. 2B, a cross-sectional structure from the semiconductor layer 22 to the selection gate electrodes 45S and 45D shown in FIG. 1 is shown.

As shown in FIG. 2A, the foundation layer 11 is divided into a plurality of block regions BLK. Between the respective block regions BLK, a block isolation region 80 is provided. In each of the plurality of block regions BLK, the stacked body 44 shown in FIG. 1 is disposed. The block isolation region 80 divides the stacked body 44 into the plurality of block regions BLK. The block region BLK is surrounded by the block isolation region 80.

When the stacked body 44 is viewed perpendicularly to the Z-direction, the non-volatile semiconductor memory device 1 is provided with a guard ring layer 81gr surrounding the stacked body 44. The guard ring layer 81gr is provided on the upper side of the stacked body 44. The guard ring layer 81gr includes, for example, polysilicon.

As shown in FIG. 2B, the stacked body 44 is provided on the semiconductor layer 22. In the stacked body 44, the plurality of electrode layers 40 and the plurality of insulating layers 42 (first insulating layers) are alternately stacked in the Z-direction. On the stacked body 44, the selection gate electrodes 45D and 45S are provided through an interlayer insulating film 43.

Each of the channel body layers 20 extends in the selection gate electrodes 45D and 45S and extends in the stacked body 44 in the stacked direction (Z-direction) of the stacked body 44 in the block regions BLK. Between each of the channel body layers 20 and each of the electrode layers 40, the memory film 30 including a charge storage layer is provided.

Between the stacked body 44 provided in one of the block regions BLK (for example, a block region BLK arbitrarily selected from the non-volatile semiconductor memory device 1) among the block regions BLK and the stacked body 44 provided in a block region BLK adjacent to the one of the block regions BLK, the block isolation region 80 is provided. In the first embodiment, a portion of the block isolation region 80 provided between the adjacent stacked bodies 44 (the adjacent block regions BLK) is defined as a block isolation region portion 80a. The block isolation region portion 80a extends in the Z-direction. The block isolation region portion 80a is in contact with both stacked bodies 44 provided on both sides thereof.

The block isolation region portion 80a has an insulating layer 80aa (second insulating layer) and an insulating layer 80ab (third insulating layer). The insulating layer 80ab is in contact with the insulating layer 80aa. The insulating layer 80ab is provided on the insulating layer 80aa. A material of the insulating layer 80aa and a material of the insulating layer 80ab are different. For example, the insulating layer 80aa includes a silicon nitride (SiNₓ), and the insulating layer 80ab includes a silicon oxide (SiOₓ). Since the block isolation region portion 80a has the insulating layer 80aa and the insulating layer 80ab, the structure of the block isolation region portion 80a is sometimes called a hybrid structure.

Further, on the block isolation region portion 80a, a guard layer 81g is provided. A material of the block isolation region portion 80a and a material of the guard layer 81g are different. The guard layer 81g includes, for example, polysilicon.

In FIG. 2A, two block regions BLK are illustrated. In fact, for example, two or more block regions BLK are arranged in the Y-direction. Due to this, the number of the guard layers 81g disposed in the Y-direction is larger than shown in FIG. 2A.

In the non-volatile semiconductor memory device 1, a plurality of regions 40c of the electrode layers 40 in the stacked body 44, which are in contact with the block isolation region portion 80a, and the plurality of regions 40a of the electrode layers 40 in the stacked body 44, which are not in contact with the block isolation region portion 80a by an insulating region 82 and are in contact with the insulating region 82, have different compositions. For example, each of the electrode layers 40, which are not in contact with the block isolation region portion 80a and are in contact with the insulating region 82, includes at least one metal by silicidation, such as a silicide, and so on. Thus, the region 40a includes at least one metal by silicidation, such as a silicide, and so on. Furthermore, the region 40c of each of the electrode layers 40 which are in contact with the block isolation region portion 80a is not silicided. Thus, one of the electrode layers 40 which are in contact with the block isolation region portion 80a has the region 40c whose composition is different from a composition of one of the electrode layers 40 which are not in contact with the block isolation region portion 80a. This reason will be described below. Furthermore, the selection gate electrodes 45S and the selection gate electrodes 45D include at least one metal, such as a silicide, and so on.

The non-volatile semiconductor memory device 1 further includes an insulating region 82 extending in the Z-direction in the stacked body 44 and the semiconductor layer. The insulating region 82 extends in the Z-direction in the block region BLK, and divides one of the electrode layers 40. The insulating region 82 extends from an upper end 44u of the one of the block regions BLK to a lowest insulating layer 42d (42) of the insulating layers 42. The insulating region 82 is provided between the pair of the channel body layers 20 in the Y-direction, and extends in the Z-direction. The region 40c is provided between the insulating region 82 nearest to the block isolation region portion 80a and the block isolation region portion 80a. The insulating region 82 is provided between one of the channel body layers 20 and a channel body layer 20 adjacent to the one of the channel body layers 20. For example, the U-shaped channel body layers 20 are arranged in the Y-direction, and between the adjacent channel body layers 20 in the Y-direction, the insulating region 82 is provided. Further, between the adjacent selection gate electrode 45S and selection gate electrode 45D, an insulating layer 83 is provided. The insulating layer 83 is also in contact with the interlayer insulating film 43.

Further, a material of the insulating layer 80aa of the block isolation region portion 80a and a material of the insulating region 82 are different. For example, the insulating region 82 includes a silicon oxide (SiOₓ).

In the non-volatile semiconductor memory device 1, the memory film 30 has an insulating film 31 (tunnel film)/a charge storage film 32/an insulating film 33 (block film) as one example. The insulating film 31 includes, for example, a silicon oxide. The charge storage film 32 includes, for example, a silicon nitride. The insulating film 33 includes, for example, a silicon oxide.

A material of the channel body layer 20 and the selection gate electrode 45 is a semiconductor material including an impurity element. The semiconductor material is, for example, one of materials selected from the group consisting of Si, SiGe, SiC, Ge, and C.

The silicide refers to a silicide using at least one or more elements among Sc, Ti, V, Cr, Mn, Fe, Co, Ni, Cu, Zn, Rh, Pd, Ag, Cd, In, Sn, La, Hf, Ta, W, Re, Os, Ir, Pt, and Au. Further, the silicidation refers to the addition of at least one or more elements among Sc, Ti, V, Cr, Mn, Fe, Co, Ni, Cu, Y, Zr, Nb, Mo, Tc, Ru, Rh, Pd, Ag, Cd, In, Sn, La, Hf, Ta, W, Re, Os, Ir, Pt, and Au to silicon.

Further, the insulating layer and the insulating film in the embodiment are selected from, for example, the following materials.

Examples of the oxide include SiO₂, Al₂O₃, Y₂O₃, La₂O₃, Gd₂O₃, Ce₂O₃, CeO₂, Ta₂O₅, HfO₂, ZrO₂, TiO₂, HfSiO, HfAlO, ZrSiO, ZrAlO, and AlSiO.

Further, the oxide is represented by the chemical formula: AB₂O₄. Here, A and B may be the same as or different from each other, and are an element selected from the group consisting of Al, Sc, Ti, V, Cr, Mn, Fe, Co, Ni, Cu, Zn, Ga, and Ge. The oxide represented by the chemical formula: AB₂O₄ corresponds to, for example, Fe₂O₄, FeAl₂O₄, Mn₁₊ₓAl₂₋ₓO_{4+y}, Co₁₊ₓAl₂₋ₓO_{4+y}, or MnOₓ.

Further, the oxide is represented by the chemical formula: ABO₃. Here, A and B may be the same as or different from each other, and are an element selected from the group consisting of Al, La, Hf, Ta, W, Re, Os, Ir, Pt, Au, Hg, Ti, Pb, Bi, Ce, Pr, Nd, Pm, Sm, Eu, Gd, Tb, Dy, Ho, Er, Tm, Yb, Lu, Sc, Ti, V, Cr, Mn, Fe, Co, Ni, Cu, Zn, Ga, Ge, Y, Zr, Nb, Mo, Tc, Ru, Rh, Pd, Ag, Cd, In, and Sn. The oxide represented by the chemical formula: ABO₃ corresponds to, for example, LaAlO₃, SrHfO₃, SrZrO₃, or SrTiO₃.

Further, an oxynitride is a compound selected from the group consisting of SiON, AlON, YON, LaON, GdON, CeON, TaON, HfON, ZrON, TiON, LaAlON, SrHfON, SrZrON, SrTiON, HfSiON, HfAlON, ZrSiON, ZrAlON, and AlSiON. The oxynitride corresponds to, for example, a material in which some of the oxygen elements in the chemical formula: AB₂O₄ or the chemical formula: ABO₃ described above are substituted with a nitrogen element.

Further, a single insulating layer and a plurality of insulating layers are preferably selected from the group consisting of SiO₂, SiN, Si₃N₄, Al₂O₃, SiON, HfO₂, HfSiON, Ta₂O₅, TiO₂, and SrTiO₃.

With respect to the Si-based insulating film such as SiO₂, SiN, or SiON, an insulating film, in which each of an oxygen element concentration and a nitrogen element concentration is 1×10¹⁸ (atoms/cm³) or more, is included. However, the plurality of insulating layers have different barrier heights. Further, the insulating layer includes a material containing an impurity atom forming a defect level or a semiconductor/metal dot (quantum dot).

The source line 47 or the bit line 48 includes at least one substance selected from the group consisting of W, WN, Al, Ti, V, Cr, Mn, Fe, Co, Ni, Cu, TiN, WSiₓ, TaSiₓ, PdSiₓ, ErSiₓ, YSiₓ, PtSiₓ, HfSiₓ, NiSiₓ, CoSiₓ, TiSiₓ, VSiₓ, CrSiₓ, MnSiₓ, and FeSiₓ.

As the electrode layers 40, a metal element simple substance or a mixture of metal elements, a silicide, an oxide, a nitride, silicon, and the like can be used. The electrode layers 40 include at least one substance selected from the group consisting of Pt, Au, Ag, TiAlN, SrRuO, Ru, RuN, Ir, Ti, V, Cr, Mn, Fe, Co, Ni, Cu, TiN, TaN, LaNiO, Al, PtIrOₓ, PtRhOₓ, Rh, TaAlN, SiTiOₓ, WSiₓ, TaSiₓ, PdSiₓ, PtSiₓ, IrSiₓ, ErSiₓ, YSiₓ, HfSiₓ, NiSiₓ, CoSiₓ, TiSiₓ, VSiₓ, CrSiₓ, MnSiₓ, and FeSiₓ. The electrode layers 40 may have a function as a barrier metal layer or an adhesive layer.

Here, a production process for silicidation of the electrode layers 40 and the selection gate electrodes 45S, 45D will be described.

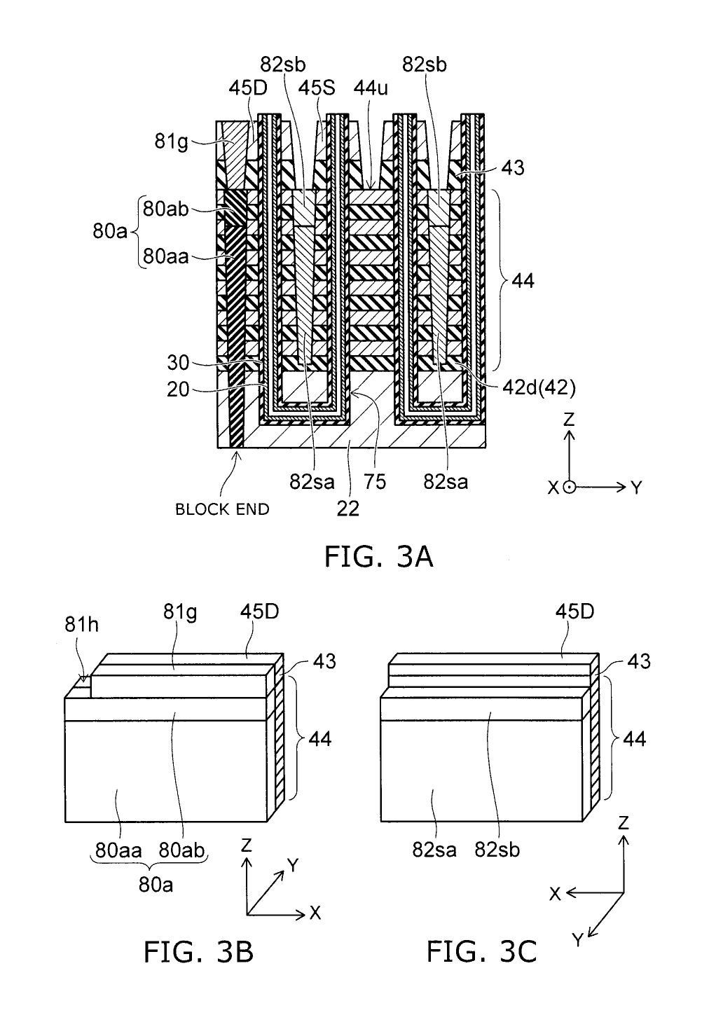

FIG. 3A to FIG. 7C are schematic views showing a silicidation process according to the first embodiment.

Here, among the FIG. 3A to FIG. 7C, the respective FIGS. 3A, 4A, 5A, 6A, and 7A are schematic cross-sectional views, and the respective FIGS. 3B, 3C, 4B, 4C, 5B, 5C, 6B, 6C, 7B, and 7C are schematic perspective views.

The respective FIGS. 3A, 4A, 5A, 6A, and 7A correspond to the position of the line A-B of FIG. 2A. The respective FIGS. 3B, 4B, 5B, 6B, and 7B show a state in which the cross section taken along the line C-D of FIG. 2A is made to face the front side, and the perspective views of the respective FIGS. 3C, 4C, 5C, 6C, and 7C show a state in which the cross section taken along the line E-F of FIG. 2A is made to face the front side. That is, the respective FIGS. 3B, 4B, 5B, 6B, and 7B show perspective views at the block end, and the respective FIGS. 3C, 4C, 5C, 6C, and 7C show perspective views at a position other than the block end.

FIG. 3A is a schematic cross-sectional view showing the silicidation process according to the first embodiment, and FIGS. 3B and 3C are schematic perspective views showing the silicidation process according to the first embodiment.

First, as shown in FIG. 3A, in each of the plurality of block regions BLK, the stacked body 44, the interlayer insulating film 43, and the selection gate electrodes 45S and 45D are formed. Further, in the stacked body 44, the channel body layer 20 and the memory film 30 are formed. At the block end, the above-described block isolation region portion 80a is formed. At this stage, the insulating layer 83 is not formed, and a region in which the insulating layer 83 is going to be formed is space.

However, at the position of the above-described insulating region 82, a sacrifice layer 82sa and a sacrifice layer 82sb provided on the sacrifice layer 82sa are formed. The sacrifice layer 82sa includes, for example, a silicon nitride, and the sacrifice layer 82sb includes, for example, a silicon oxide.

Here, as shown in FIG. 2A, the guard layer 81g is not in contact with the guard ring layer 81gr. Between the guard layer 81g and the guard ring layer 81gr, a hole portion 81h is provided. By providing the hole portion 81h so that the guard layer 81g and the guard ring layer 81gr are not in contact with each other, electrical contact between the guard layer 81g and the guard ring layer 81gr is avoided. If the guard layer 81g and the guard ring layer 81gr are in contact with each other and an electrical connection is established between the guard layer 81g and the guard ring layer 81gr, an electrical short circuit occurs in all the selection gate electrodes 45 in contact with the respective guard layers 81g. In order to avoid this, the hole portion 81h is provided so that the guard layer 81g and the guard ring layer 81gr are not in contact with each other.

Further, by forming the guard layer 81g, collapse, warpage, distortion, or the like of the stacked body 44 at the block end during the process is prevented. Further, by forming the guard layer 81g to prevent collapse or the like, the number of stacked layers of the electrode layers 40 in the Z-direction can be further increased.

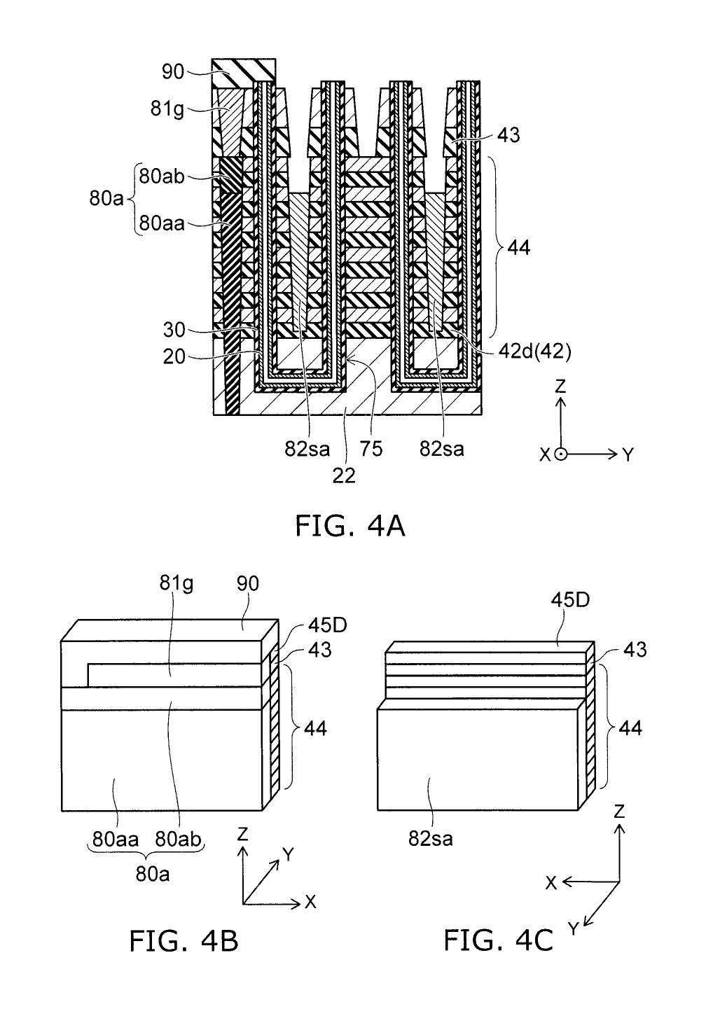

FIG. 4A is a schematic cross-sectional view showing the silicidation process according to the first embodiment, and FIGS. 4B and 4C are schematic perspective views showing the silicidation process according to the first embodiment.

Next, a mask layer 90 which covers the guard layer 81g and the block isolation region portion 80a is formed. Subsequently, the sacrifice layer 82sb is wet-etched to selectively remove the sacrifice layer 82sb containing a silicon oxide.

In this wet etching, a solution (for example, a diluted hydrofluoric acid solution) with which the mask layer 90 is hardly etched and the sacrifice layer 82sb is selectively etched is used. Here, the insulating layer 80ab contains a silicon oxide, but is covered with the mask layer 90. Therefore, the insulating layer 80ab is not etched with the solution. Thereafter, the mask layer 90 is removed.

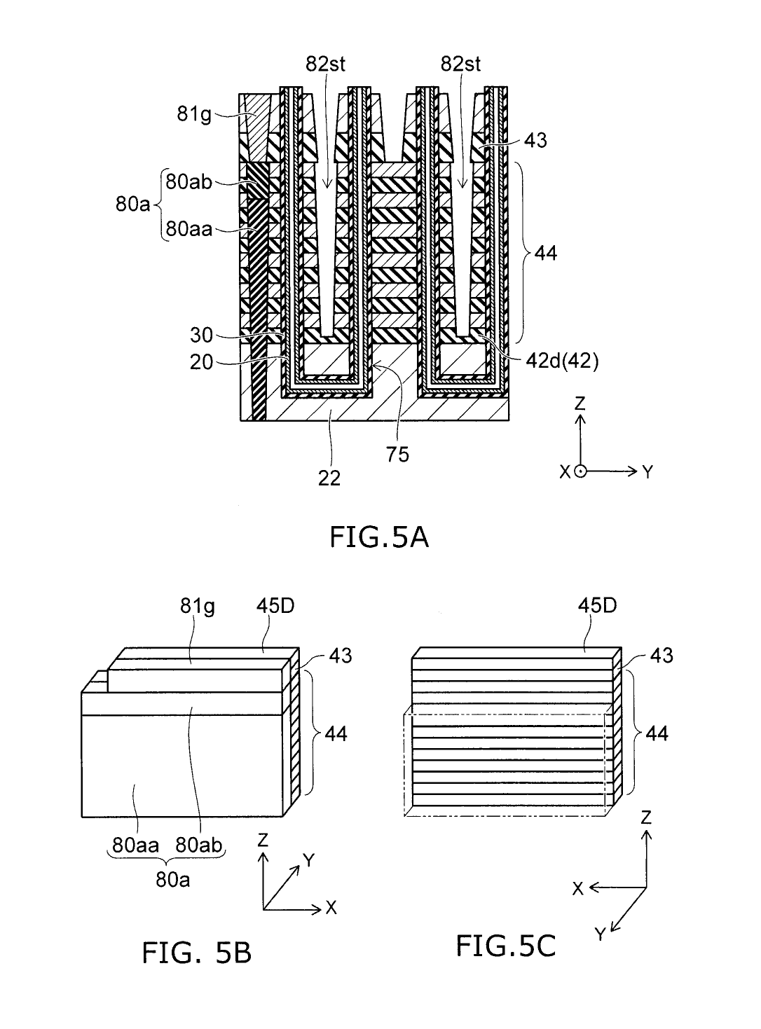

FIG. 5A is a schematic cross-sectional view showing the silicidation process according to the first embodiment, and FIGS. 5B and 5C are schematic perspective views showing the silicidation process according to the first embodiment.

Next, the sacrifice layer 82sa is wet-etched to selectively remove the sacrifice layer 82sa. Here, the guard layer 81g is selectively provided on the block isolation region portion 80a. The insulating layer 80ab is provided on the insulating layer 80aa. The material of the portion (the insulating layer 80ab) of the block isolation region portion 80a exposed from the guard layer 81g is different from the material of the sacrifice layer 82sa.

In this wet etching, a solution (for example, a phosphoric acid solution) with which the insulating layer 80ab containing a silicon oxide is hardly etched and the sacrifice layer 82sa containing a silicon nitride is selectively etched is used. By doing this, a slit 82st (hole) is formed between the channel body layers 20 which extend in the Z-direction and are arranged in the Y-direction in the block region BLK.

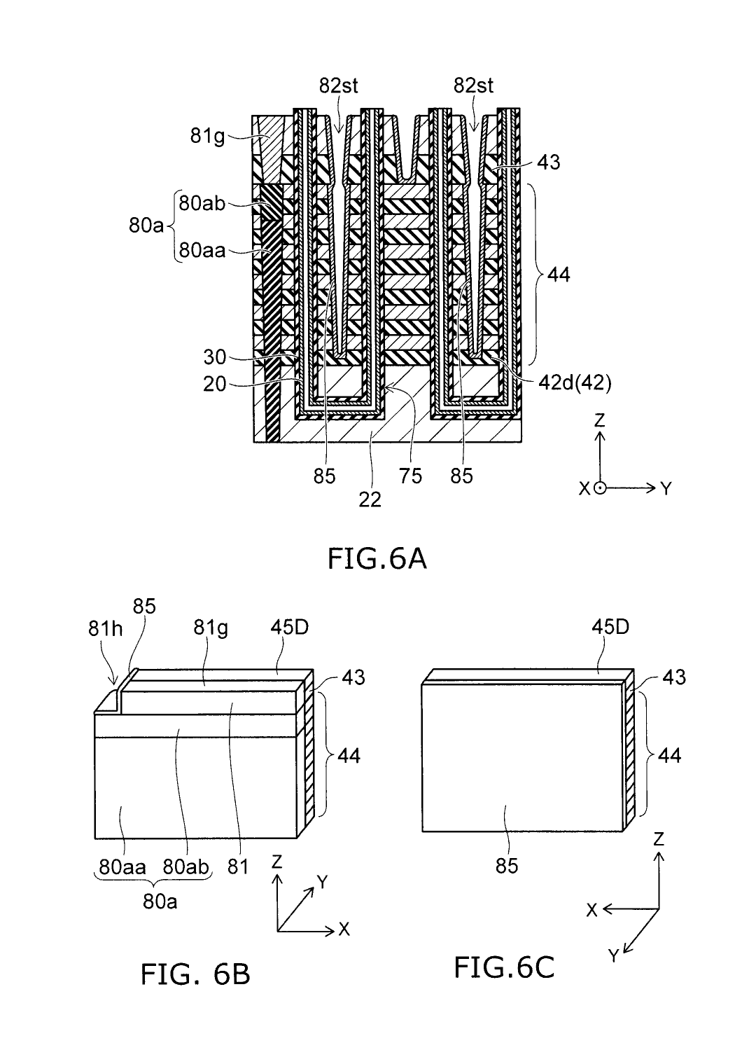

FIG. 6A is a schematic cross-sectional view showing the silicidation process according to the first embodiment, and FIGS. 6B and 6C are schematic perspective views showing the silicidation process according to the first embodiment.

Next, in the slit 82st, a metal film 85 is formed by one of methods of a sputtering method, a CVD (Chemical Vapor Deposition) method, an ALD (Atomic Layer Deposition) method, or the like. The metal film 85 includes, for example, nickel (Ni). The metal film 85 is formed on the insulating layer 80ab in the vicinity of the hole portion 81h and also on the guard layer 81g.

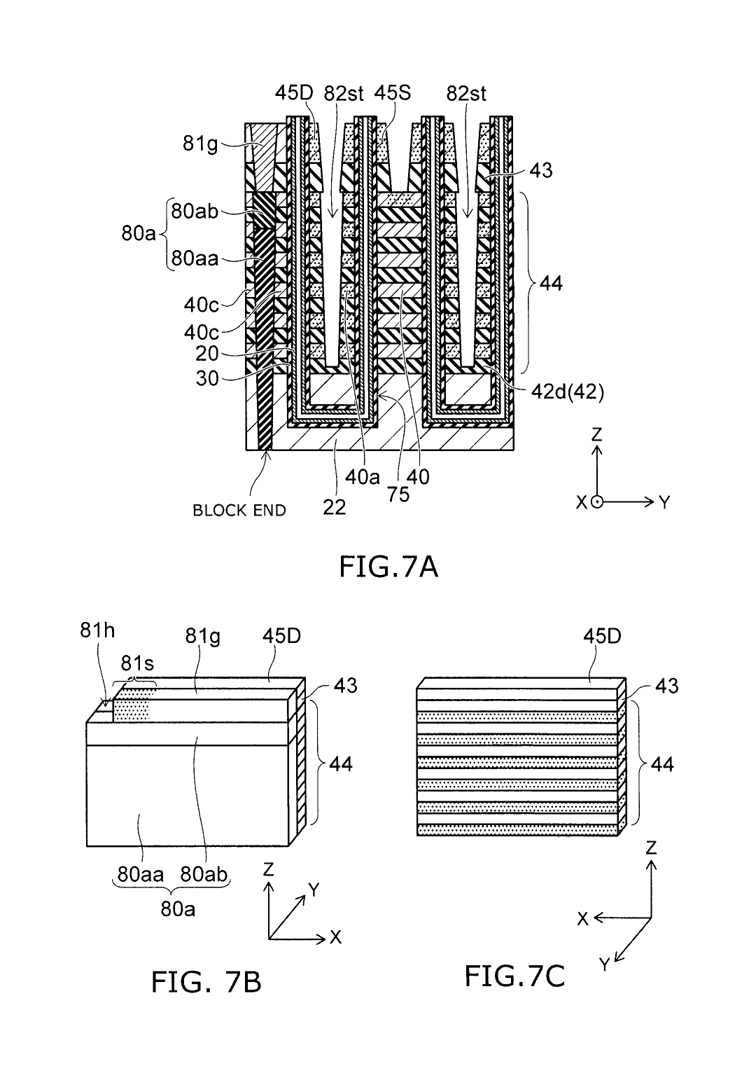

FIG. 7A is a schematic cross-sectional view showing the silicidation process according to the first embodiment, and FIGS. 7B and 7C are schematic perspective views showing the silicidation process according to the first embodiment.

Next, the metal film 85 is heated to silicide the electrode layer 40 and the selection gate electrodes 45S and 45D, diffusing metal in the metal film 85 into the electrode layer 40 and the selection gate electrodes 45S and 45D. Thus, a resistance of one of the electrode layer 40 and the selection gate electrodes 45S and 45D becomes low. Here, the region 40c which is in contact with the block isolation region portion 80a and the selection gate electrodes 45S and 45D which are in contact with the guard layer 81g are not silicided. This is because the block isolation region portion 80a is provided on the lower side of the guard layer 81g. In other words, the metal film 85 is not in contact with the electrode layer 40 and the selection gate electrodes 45S and 45D at the block end.

Incidentally, the metal film 85 is formed also on the guard layer 81g in the vicinity of the hole portion 81h, and therefore, the guard layer 81g is silicided in the vicinity of the hole portion 81h. In the guard layer 81g, the concentration of the metal (nickel) contained in the guard layer 81g decreases as it goes away from the guard ring layer 81gr.

Thereafter, as shown in FIG. 2B, in the slit 82st, the insulating region 82 is formed, and between the adjacent selection gate electrodes 45, the insulating layer 83 is formed. Incidentally, after the electrode layer 40 and the selection gate electrodes 45S and 45D are silicided, the residue of the metal film 85 may be removed by wet etching.

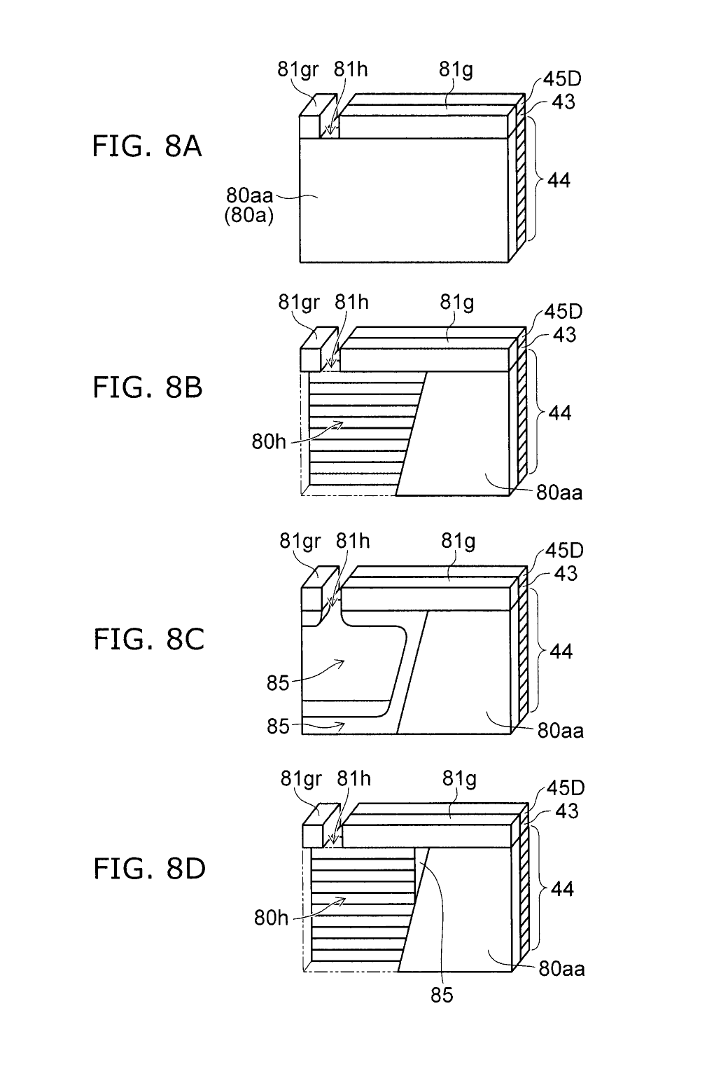

FIG. 8A to FIG. 8D are schematic perspective views showing a silicidation process according to a reference example.

FIG. 8A to FIG. 8D show a state in which the cross section taken along the line C-D of FIG. 2A is made to face the front side. That is, FIG. 8A to FIG. 8D show perspective views facing the same side as shown in the respective FIGS. 3B, 4B, 5B, 6B, and 7B.

For example, as shown in FIG. 8A, a case where the block isolation region portion 80a is formed only of the insulating layer 80aa composed of a silicon nitride is supposed.

In such a case, when the sacrifice layer 82sa is etched, because the component of the block isolation region portion 80a and the component of the sacrifice layer 82sa are the same, the insulating layer 80aa is eroded by an etching solution penetrating through the hole portion 81h. Due to this, as shown in FIG. 8B, a space 80h is formed below the hole portion 81h.

Subsequently, when the metal film 85 is formed in the slit 82st in order to silicide the electrode layer 40, the metal film 85 intrudes into the space 80h from the hole portion 81h as shown in FIG. 8C. Due to this, the metal film 85 comes in contact with the stacked body 44.

Once the metal film 85 intrudes into the space 80h, this metal film 85 is hardly removed by the following treatment (for example, wet etching), and as shown in FIG. 8D, the metal film 85 may remain as a residue in the space 80h. As a result, an electrical short circuit sometimes occurs between the upper and the lower electrode layers 40 through the metal film 85, or between the stacked bodies 44 across the adjacent block regions BLK.

On the other hand, in the first embodiment, the insulating layer 80ab having a different component from that of the insulating layer 80aa is provided below the hole portion 81h, and therefore, a space 80h is not formed. Due to this, the metal film 85 does not intrude into the space 80h. As a result, an electrical short circuit does not occur between the upper and the lower electrode layers 40 through the metal film 85, nor between the stacked bodies 44 across the adjacent block regions BLK.

### Variation 1 of First Embodiment

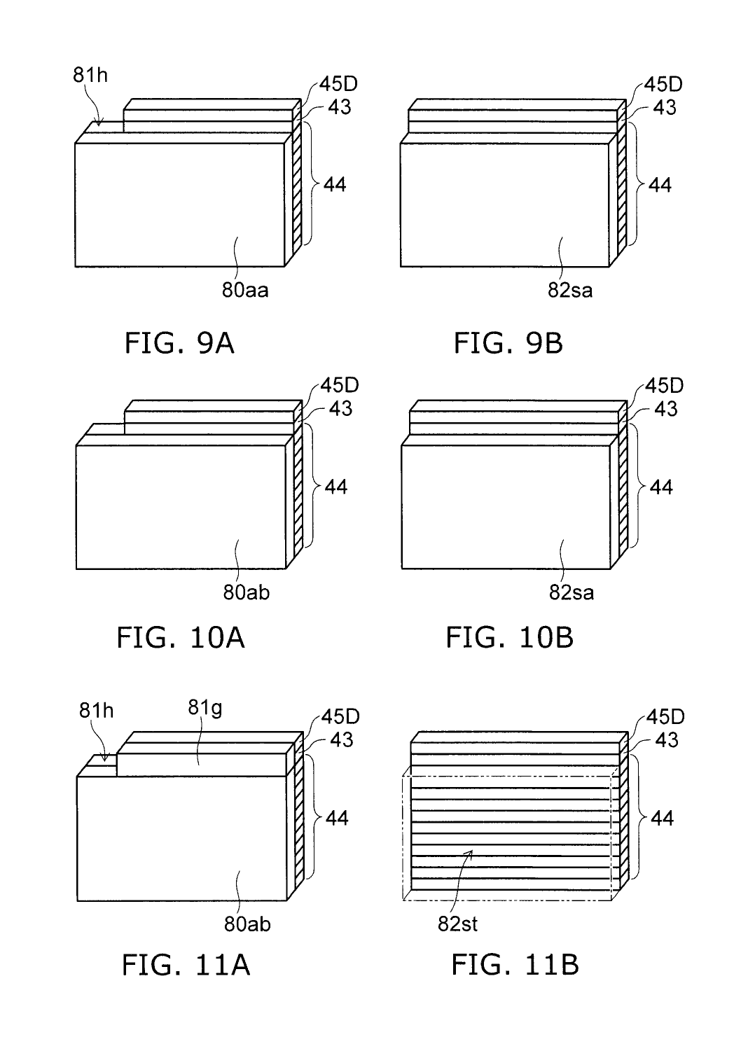

FIG. 9A to FIG. 11B are schematic perspective views showing a silicidation process according to a variation 1 of the first embodiment.

FIGS. 9A, 10A, and 11A show a state in which the cross section taken along the line C-D of FIG. 2A is made to face the front side, and FIGS. 9B, 10B, and 11B show a state in which the cross section taken along the line E-F of FIG. 2A is made to face the front side. The respective FIGS. 9A, 10A, and 11A show perspective views at the block end, and the respective FIGS. 9B, 10B, and 11B show perspective views at a position other than the block end.

As shown in FIG. 9A, in the block region BLK, the insulating layer 80aa is formed. Further, as shown in FIG. 9B, in a portion in which the insulating region 82 is going to be formed, the sacrifice layer 82sa is formed.

Next, as shown in FIG. 10A, in the block region BLK, the insulating layer 80aa is replaced with the insulating layer 80ab. For example, the insulating layer 80aa containing a silicon nitride is selectively removed by wet etching, and in this portion in which the insulating layer 80aa was removed, the insulating layer 80ab containing a silicon oxide is formed by a CVD method, an ALD method, or the like.

Here, on the sacrifice layer 82sa shown in FIG. 10B, a mask layer (not shown) is formed, and the sacrifice layer 82sa is protected by the mask layer. Due to this, the sacrifice layer 82sa shown in FIG. 10B is not removed. By doing this, a state in which the material of the insulating layer 80ab and the material of the sacrifice layer 82sa in the block region BLK are different is obtained.

Next, as shown in FIG. 11A, in the block region BLK, the guard layer 81g is formed on the insulating layer 80ab. Further, as shown in FIG. 11B, the sacrifice layer 82sa is removed by wet etching. By doing this, a portion in which the sacrifice layer 82sa was formed becomes the slit 82st.

Thereafter, in the slit 82st, the metal film 85 (not shown in FIG. 11B) is formed by one of a sputtering method, a CVD method, an ALD method, and the like. Then, the metal film 85 is subjected to a heat treatment, whereby the electrode layer 40 and the selection gate electrodes 45S and 45D are silicided.

At this time, in the block region BLK, the region 40c is in contact with the insulating layer 80ab, and therefore, the region 40c is not silicided. Also according to such a method, an electrical short circuit between the upper and the lower electrode layers 40 and an electrical short circuit between the adjacent block regions BLK can be prevented.

Incidentally, after the electrode layer 40 is silicided, in the slit 82st, the insulating region 82 is formed. At this time, the material of the insulating region 82 and the material of the block isolation region portion 80a contain a silicon oxide. That is, the material of the insulating region 82 and the material of the block isolation region portion 80a are the same.

### Variation 2 of First Embodiment

The method for preventing the silicidation of the region 40c in the block region BLK is not limited to the above-described method.

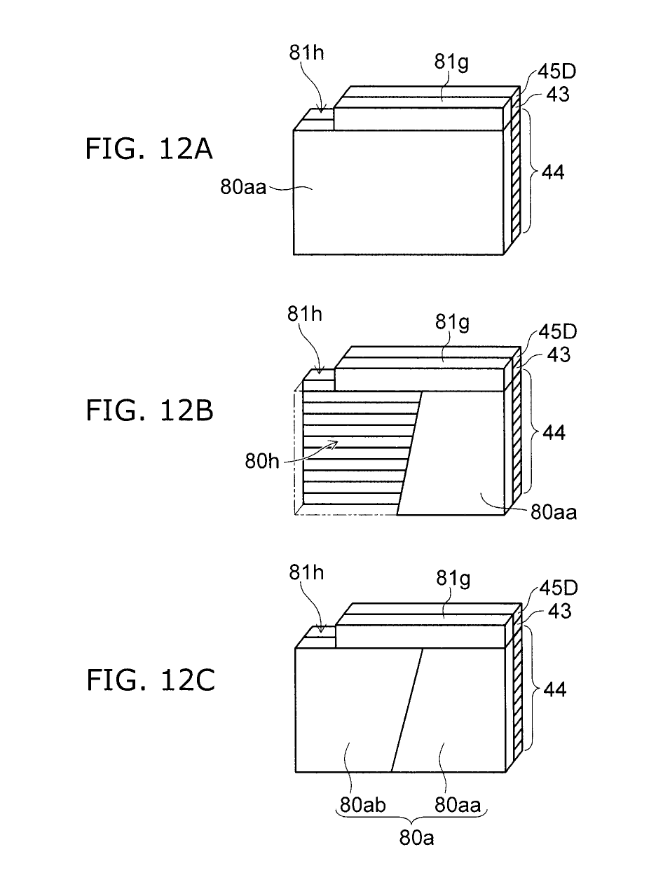

FIG. 12A to FIG. 12C are schematic perspective views showing a silicidation process according to a variation 2 of the first embodiment.

FIG. 12A to FIG. 12C show a state in which the cross section taken along the line C-D of FIG. 2A is made to face the front side. FIG. 12A to FIG. 12C show perspective views at the block end.

First, as shown in FIG. 12A, in the block region BLK, the insulating layer 80aa is formed. On the insulating layer 80aa, the guard layer 81g is formed. The guard layer 81g has the hole portion 81h

Next, as shown in FIG. 12B, in the block region BLK, an etching solution is allowed to flow through the hole portion 81h, thereby removing a part of the insulating layer 80aa. By doing this, the space 80h is formed below the hole portion 81h.

Next, as shown in FIG. 12C, in the space 80h, the insulating layer 80ab is formed by one of a CVD method, an ALD method, and the like. That is, the block isolation region portion 80a formed in the block region BLK has the insulating layer 80ab and the insulating layer 80aa. The insulating layer 80ab is provided beside the insulating layer 80aa.

In the block region BLK, the region 40c is in contact with the block isolation region portion 80a, and therefore, the region 40c is not silicided. Also according to such a method, an electrical short circuit between the upper and the lower electrode layers 40 and an electrical short circuit between the adjacent block regions BLK can be prevented.

### Variation 3 of First Embodiment

The parasitic capacitance of the block isolation region portion 80a may be reduced by forming a void in the block isolation region portion 80a.

For example, at the stage shown in FIG. 12C described above, the block isolation region portion 80a is formed such that the insulating layer 80ab is not completely formed in the space 80h, but the space 80h remains therein. Here, the insulating layer 80ab is formed under the conditions that the step coverage is not sufficient.

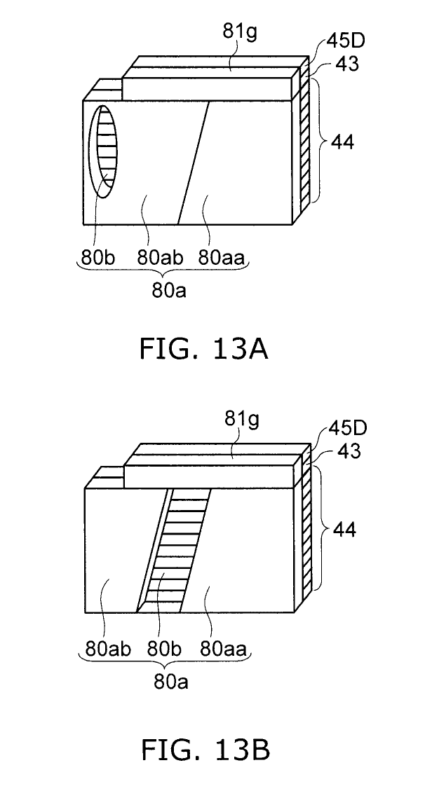

FIG. 13A to FIG. 13B are schematic perspective views showing a silicidation process according to a variation 3 of the first embodiment.

FIG. 13A to FIG. 13B show a state in which the cross section taken along the line C-D of FIG. 2A is made to face the front side. FIG. 13A to FIG. 13B show perspective views at the block end.

For example, as shown in FIG. 13A, a void 80b is formed in the insulating layer 80ab. Alternatively, the void 80b may be formed in the insulating layer 80aa.

Further, as shown in FIG. 13B, the void 80b may be formed between the insulating layer 80aa and the insulating layer 80ab.

Incidentally, in order to prevent the collapse of the stacked body 44 at the block end, the ratio of the volume of the void 80b to the volume of the block isolation region portion 80a is adjusted to 50% or less. Alternatively, the ratio (filling ratio) of the volume of the block isolation region portion 80a to the volume of the space 80h is adjusted to 30% or more.

### Second Embodiment

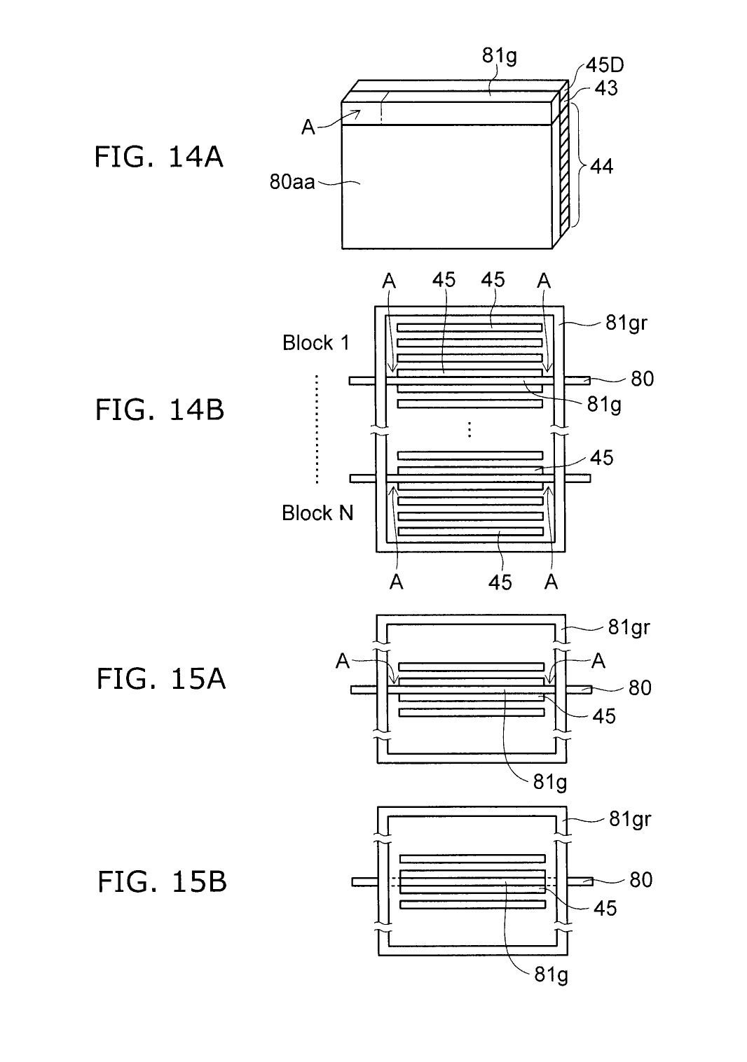

FIG. 14A is a schematic cross-sectional view showing a production process according to a second embodiment, and FIG. 14B is a schematic plan view showing the production process according to the second embodiment.

In the second embodiment, the guard layer 80g is formed throughout the block isolation region portion 80a to silicide the electrode layer 40. That is, the guard layer 81g is provided also in a portion indicated by the arrow A without providing the hole portion 81h in the guard layer 81g, and the process is allowed to proceed.

According to such a configuration, since the guard layer 81g does not have a hole portion 81h, an etching solution does not flow through the hole portion 81h, or a space 80h is not formed below the hole portion 81h. Due to this, the region 40c is not silicided. Further, an electrical short circuit between the upper and the lower electrode layers 40 and an electrical short circuit between the adjacent block regions BLK are prevented.

However, in the second embodiment, the selection gate electrode 45 which is in contact with the guard layer 81g is electrically connected to the guard ring layer 81gr through the guard layer 81g. Therefore, the selection gate electrode 45 which is in contact with the guard layer 81g is not used as a selection gate electrode, but is used as a dummy layer. Incidentally, by storing data to be stored in the memory cell MC below the selection gate electrode 45 serving as a dummy layer in, for example, a column redundancy region, a decrease in memory capacity is prevented.

### Variation 1 of Second Embodiment

FIG. 15A is a schematic cross-sectional view showing a production process according to a variation 1 of the second embodiment, and FIG. 15B is a schematic plan view showing the production process according to the variation 1 of the second embodiment.

In addition, after the process for silicidation of a portion indicated by the arrow A is completed, the portion is removed by RIE again, whereby the guard layer 81g and the guard ring layer 81gr can be separated from each other. That is, the selection gate electrode 45 which is in contact with the guard layer 81g can be used as a selection gate electrode.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A non-volatile semiconductor memory device, comprising:
a stacked body including a plurality of electrode layers and a plurality of first insulating layers alternately stacked;
an isolation region extending in the stacked body, the isolation region dividing the stacked body into a plurality of first regions;
a plurality of first semiconductor members extending in one of the first regions in a stacked direction of the stacked body;
a memory film provided between one of the first semiconductor members and one of the electrode layers; and
an insulating region extending in the one of the first regions in the stacked direction, the insulating region extending from an upper end of the one of the first regions to a lowest first insulating layer of the first insulating layers,
a composition of a second region of the one of the electrode layers being different from a composition of a third region of the one of the electrode layers, the second region being in contact with the insulating region, the third region being in contact with the isolation region.

2. The device according to claim 1, further comprising a semiconductor layer below the stacked body, the isolation region extending in the stacked body in the semiconductor layer.

3. The device according to claim 1, wherein the insulating region is provided between a pair of first semiconductor members of the first semiconductor members.

4. The device according to claim 1, wherein the second region includes at least one metal.

5. The device according to claim 1, further comprising a selection gate electrode provided on one of the first regions, the selection gate electrode including at least one metal.

6. The device according to claim 1, further comprising a guard layer provided on the isolation region.

7. The device according to claim 1, wherein the isolation region between the adjacent first regions has a second insulating layer and a third insulating layer being in contact with the second insulating layer, and
a material of the second insulating layer is different from a material of the third insulating layer.

8. The device according to claim 7, wherein the third insulating layer is provided on the second insulating layer.

9. The device according to claim 7, wherein the third insulating layer is provided beside the second insulating layer.

10. The device according to claim 7, wherein a space is formed in one of the second insulating layer or the third insulating layer.

11. The device according to claim 7, wherein a space is formed between the second insulating layer and the third insulating layer.

12. The device according to claim 7, wherein a material of the second insulating layer of the isolation region is different from a material of the insulating region.

13. The device according to claim 7, wherein a material of the isolation region and a material of the insulating region being same.

14. The device according to claim 1, further comprising a guard layer provided on the isolation region.

15. The device according to claim 14, further comprising a guard ring layer provided on an upper side of the stacked body and surrounding the stacked body when viewing the stacked body perpendicularly to the stacked direction, the guard layer not being in contact with the guard ring layer.

16. The device according to claim 1, further comprising a second semiconductor member in the semiconductor layer, the second semiconductor member including a pair of first portions extending in the stacked direction and a second portion connected to the first portions, the second portion extending in a direction crossing the stacked direction, an insulating film being provided between the second semiconductor member and the semiconductor layer, each of the pair of the first semiconductor member being connected to each of the pair of first portions.

17. A method for manufacturing a non-volatile semiconductor memory device, comprising:
forming a structure body including a stacked body including a plurality of electrode layers and a plurality of first insulating layers alternately stacked, an isolation region extending in the stacked body, the isolation region dividing the stacked body into a plurality of first regions, a plurality of first semiconductor members extending in one of the first regions in a stacked direction of the stacked body, a memory film provided between one of the first semiconductor members and one of the electrode layers, and a sacrifice layer extending in the one of the first regions in the stacked direction, the sacrifice layer dividing the electrode layers;
forming a hole in the one of the first regions by selectively removing the sacrifice layer;
forming a metal film in the hole; and
diffusing a metal in the metal film into the electrode layers from the hole side.

18. The method according to claim 17, wherein a material included in the sacrifice layer is different from a material included in the isolation region.

19. The method according to claim 17, wherein a guard layer is selectively provided on the isolation region, a material of the isolation region exposed from the guard layer is different from a material of the sacrifice layer when removing the sacrifice layer.

20. The method according to claim 17, wherein the isolation region has a second insulating layer and a third insulating layer provided on the second insulating layer, and a material of the third insulating layer is different from a material of the sacrifice layer.
